(19) United States
(12) Patent Application Publication
(10) Pub. No.: US 2025/0207250 A1
(43) Pub. Date: Jun. 26, 2025

(54) SUBSTRATE PROCESSING APPARATUS AND SUBSTRATE PROCESSING METHOD

(71) Applicant: Tokyo Electron Limited, Tokyo (JP)

(72) Inventors: Tsutomu HIROKI, Yamanashi (JP); Shingo KANEMARU, Yamanashi (JP)

(21) Appl. No.: 18/849,113

(22) PCT Filed: Mar. 13, 2023
(86) PCT No.: PCT/JP2023/009542

§ 371 Date: Sep. 20, 2024

(30) Foreign Application Priority Data
Mar. 24, 2022 (JP) 2022-048862
Aug. 25, 2022 (JP) 2022-134010

(51) Int. Cl. C23C 16/44; H01L 21/285

(52) U.S. Cl. CPC C23C 16/4412; H01L 21/28568

(57) ABSTRACT

A substrate processing apparatus includes a processing chamber configured to accommodate a substrate in an internal space; a susceptor configured to mount the substrate in the internal space; a gas supply configured to supply a processing gas to the internal space; and a gas exhaust section configured to exhaust an exhaust gas containing the processing gas from the internal space. The gas exhaust section includes one or more exhaust ports communicating with the internal space of the processing chamber and extending along a circumferential direction of an inner circumferential surface of the processing chamber, the exhaust gas flowing into the one or more exhaust ports, and a plurality of exhaust passages communicating with the one or more exhaust ports and extending inside a wall of the processing chamber.

### TECHNICAL FIELD

The present disclosure relates to a substrate processing apparatus and a substrate processing method.

### BACKGROUND

A substrate processing apparatus is required to cause a processing gas supplied into an internal space of the processing chamber to flow so as to be uniformly diffused around a substrate, in order to improve in-plane uniformity of substrate processing. For example, in a conventional substrate processing apparatus, a baffle plate is installed around a mounting table, on which a substrate is mounted, to adjust a flow direction of a processing gas.

Additionally, Patent Documents 1 and 2 disclose a configuration including multiple manifolds for transferring a processing gas or a processing liquid to a processing chamber (mixing chamber). The multiple manifolds are formed to have substantially the same length with respect to the processing chamber.

### RELATED ART DOCUMENT

### Patent Document

Patent Document 1: Japanese Laid-open Patent Application Publication No. 2017-152684
Patent Document 2: Japanese Laid-open Patent Application Publication No. 2017-152685

### SUMMARY OF THE INVENTION

### Problem to be solved by the invention

The present disclosure provides a technique of uniformly exhausting an exhaust gas from a processing chamber, thereby improving in-plane uniformity of substrate processing.

### Means for Solving the Problem

According to an aspect of the present disclosure, there is provided a substrate processing apparatus including a processing chamber configured to accommodate a substrate in an internal space; a susceptor configured to mount the substrate in the internal space; a gas supply configured to supply a processing gas to the internal space; and a gas exhaust section configured to exhaust an exhaust gas containing the processing gas from the internal space, wherein the gas exhaust section includes one or more exhaust ports communicating with the internal space of the processing chamber and extending along a circumferential direction of an inner circumferential surface of the processing chamber, the exhaust gas flowing into the one or more exhaust ports, and a plurality of exhaust passages communicating with the one or more exhaust ports and extending inside a wall of the processing chamber.

### Effect of the Invention

According to an aspect, in-plane uniformity of substrate processing can be improved by uniformly exhausting an exhaust gas from a processing chamber.

### BRIEF DESCRIPTION OF THE DRAWINGS

FIG. 1 is a vertical sectional view schematically illustrating a configuration of a substrate processing apparatus according to an embodiment.

FIG. 2 is a perspective view schematically illustrating a configuration of a chamber body.

FIG. 3 is a plan sectional view of the chamber body at a position where an exhaust port is formed.

FIG. 4 is an enlarged side sectional view illustrating a part of a configuration of an exhaust section.

FIG. 5 is a plan sectional view of a chamber body at a position where an exhaust port is formed according to a modified example.

DESCRIPTION OF THE EMBODIMENTS

In the following, embodiments of the present disclosure will be described with reference to the drawings. In the drawings, the same components are denoted by the same reference symbols, and a duplicated description thereof may be omitted.

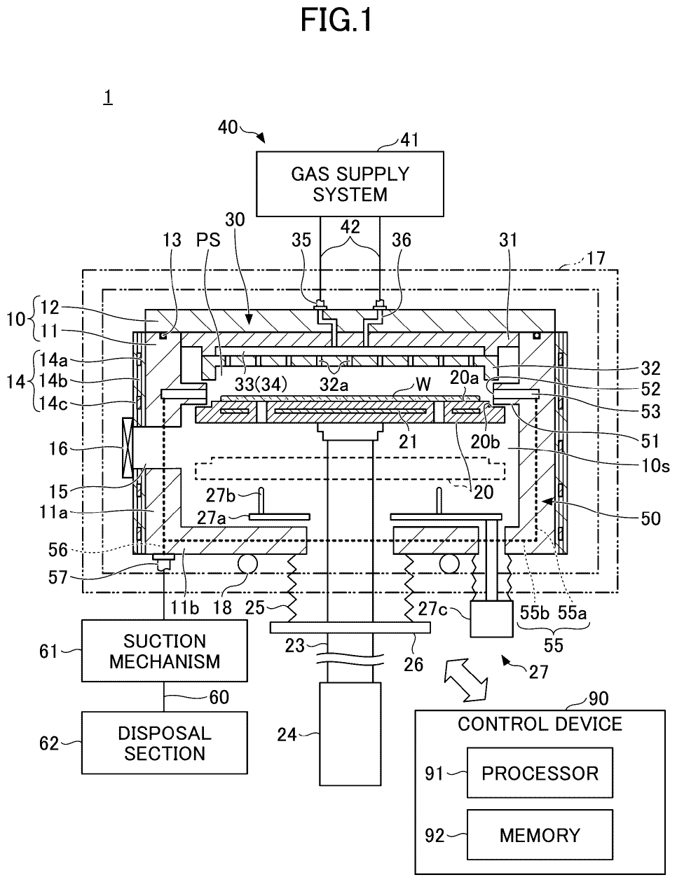

FIG. 1 is a vertical sectional view schematically illustrating a configuration of a substrate processing apparatus 1 according to an embodiment. As illustrated in FIG. 1, the substrate processing apparatus 1 is configured as an apparatus that forms a film on a surface of a substrate W by an atomic layer deposition (ALD) method. The substrate W on which the film deposition process is performed may be a semiconductor substrate, such as a silicon wafer or a compound semiconductor wafer, or the like. Additionally, the film formed on the substrate W is not particularly limited, and may be one of a metal film, a metal oxide film, a metal nitride film, a silicon film, a silicon oxide film, a silicon nitride film, or the like. In the following, as the film deposition process, a configuration in which a tungsten film, which is an example of a metal film, is formed on the surface of the substrate W will be representatively described.

Specifically, the substrate processing apparatus 1 includes a susceptor 20, a shower head 30, a gas supply 40, and a gas exhaust section 50 as components installed or connected to a processing chamber 10. The substrate processing apparatus 1 further includes a control device 90 configured to control the components to perform a film deposition process.

The processing chamber 10 includes a chamber body 11 having a recessed shape in a side sectional view in which a cylindrical sidewall 11a and a circular bottom wall 11b are continuously formed, and a cover 12 configured to cover an upper opening of the chamber body 11. An upper end of the sidewall 11a and a lower surface of the cover 12 are airtightly fixed such that a seal member 13 is interposed between the upper end of the sidewall 11a and the lower surface of the cover 12, so that an internal space 10s for accommodating the substrate W is formed in the processing chamber 10.

As a material forming the processing chamber 10 (the chamber body 11 and the cover 12), a low thermal expansion material is preferably applied. Examples of the low thermal expansion material include stainless steel, in which iron, chromium, nickel, and the like are mixed. By applying stainless steel as described, the processing chamber 10 has a lower heat transfer coefficient than that of aluminum alloy or the like, but has higher heat resistance, and thus can suppress deformation during substrate processing. With this, the processing chamber 10 can satisfactorily perform the substrate processing in a high-temperature environment of, for example, 250° C. or greater. Here, the low thermal expansion material of the processing chamber 10 is not limited to stainless steel, and various materials having heat resistance may be applied. For example, a low thermal expansion metal, a low thermal expansion alloy (invar), a low thermal expansion ceramic (an inorganic material), or the like may be employed.

Additionally, the processing chamber 10 includes a cylindrical heating body 14 configured to heat the processing chamber 10 on the sidewall 11a of the chamber body 11. A thermal spray heater in which a heat generating material is directly plasma-sprayed to the processing chamber 10 is applied to the heating body 14.

For example, the heating body 14 is formed in a laminated structure in which an insulating layer 14a, an interconnect layer 14b, and an insulating layer 14c are laminated in the order from the outer circumferential surface of the chamber body 11 toward the outside in the radial direction. An appropriate ceramic material that can be coated on the chamber body 11 by thermal spraying is applied to the insulating layers 14a and 14c. The interconnect layer 14b is formed by patterning a metallic material, such as tungsten, which can be in close contact with a ceramic material and has high electrical conductivity, on an appropriate interconnect path, for example. Here, the metallic material of the interconnect layer 14b is not particularly limited, and copper, aluminum, nickel, or the like can be applied. The interconnect electrically connected to the interconnect path of the interconnect layer 14b is connected to a heating power source (not illustrated) provided outside the heating body 14, and the heating body 14 heats the entire chamber body 11 based on the power supply from the heating power source.

Here, the substrate processing apparatus 1 may have a configuration in which an outer chamber 17 (see a two dot chain line in FIG. 1) is installed outside the processing chamber 10 in order to maintain a high-temperature environment of the processing chamber 10. That is, the substrate processing apparatus 1 can increase the heat insulation property by generating a space between the processing chamber 10 and the outer chamber 17. With this, heat radiation from the processing chamber 10 to the outside is suppressed, and the heating amount (the electric power amount) by the heating body 14 is reduced. Here, by disposing ball-shaped members 18 as supports of the processing chamber 10 on the bottom surface of the outer chamber 17, a gap is formed between the processing chamber 10 and the outer chamber 17, and thus the heat insulation property can be further increased.

The substrate processing apparatus 1 further includes a carry in/out port 15 for carrying in and out the substrate W and a gate valve 16 for opening and closing the carry in/out port 15 at a predetermined position of the side (the sidewall 11a and the heating body 14) of the processing chamber 10.

With respect to the above, the susceptor 20 is made of nickel or the like and is supported by a support member 23 in the processing chamber 10. The susceptor 20 is formed in a planar shape (a circle shape) corresponding to the substrate W, and has a mounting surface 20a for horizontally supporting the substrate W on the upper surface thereof. Additionally, the susceptor 20 includes a heater 21 for heating the substrate W mounted on the mounting surface 20a inside the susceptor 20. The heater 21 generates heat by being supplied with power from a heater power source (not illustrated).

The support member 23 supporting the susceptor 20 extends below the processing chamber 10 from the center of the bottom surface of the susceptor 20 through a hole formed in the bottom wall 11b of the processing chamber 10, and the lower end thereof is connected to a vertical movement mechanism 24. The susceptor 20 is raised and lowered by the vertical movement mechanism 24 via the support member 23. Specifically, the vertical movement mechanism 24 displaces the susceptor 20 between a processing position at which the film deposition process is performed on the substrate W and a transfer position, below the processing position, at which the substrate W can be transferred. When the susceptor 20 is raised to the processing position, a processing space PS for the substrate processing is formed between the shower head 30 and the susceptor 20 in the internal space 10s of the processing chamber 10. Additionally, a bellows 25 that expands and contracts in accordance with the susceptor 20 moving up and down and a flange 26 that closes the lower end of the bellows 25 are provided below the processing chamber 10 in the vertical direction.

Further, the processing chamber 10

includes a substrate lifter 27 at the bottom wall 11b. The substrate lifter 27 includes a lifting plate 27a, multiple (for example, three) support pins 27b protruding upward from the lifting plate 27a, and a pin vertical movement mechanism 27c that raises and lowers the lifting plate 27a. When the substrate W is carried into the processing chamber 10, the substrate lifter 27 receives the substrate W by raising the support pins 27b with respect to the substrate W transferred by a transfer device (not illustrated), and then mounts the substrate W on the susceptor 20 at the transfer position by lowering the support pins 27b. Conversely, when the substrate W is carried out from the processing chamber 10, the substrate lifter 27 raises the support pins 27b to float the substrate W from the susceptor 20 at the transfer position and delivers the substrate W to the transfer device that has entered.

The shower head 30 is formed of, for example, stainless steel, and is attached to the lower surface of the cover 12 such that the shower head 30 is disposed to face the mounting surface 20a of the susceptor 20. The shower head 30 includes a base 31 and a shower plate 32.

The base 31 is formed in a substantially cylindrical shape and has a recess 34 serving as a gas diffusion space 33 at the center of the lower side thereof in the vertical direction. Additionally, the shower head 30 includes multiple (two) supply ports 35 provided at the upper portion of the cover 12, and a gas flow path 36 communicating a flow path of the supply port 35 with the gas diffusion space 33 between the cover 12 and the base 31.

The shower plate 32 is attached to the lower side of the base 31 in the vertical direction so as to cover the recess 34. The gas diffusion space 33 is formed by the base 31 and the shower plate 32. The shower plate 32 has multiple gas discharge holes 32a through which the gas is discharged from the gas diffusion space 33.

The gas supply 40 supplies a processing gas to the shower head 30. The gas supply 40 includes a gas supply system 41 configured to supply multiple kinds of processing gases and multiple (two) supply paths 42 connected from the gas supply system 41 to the supply port 35. When a tungsten film is formed, the gas supply system 41 supplies a tungsten chloride gas (WCl₆ gas), which is a tungsten-containing gas, an Hz gas, which is a reducing gas, an N₂ gas, which is a purge gas, and the like. For example, the gas supply system 41 simultaneously supplies the WCl₆ gas and the N₂ gas from one path among the two supply paths 42, and guides the WCl₆ gas to the processing space PS to be adsorbed on the surface of the substrate W. Then, the gas supply system 41 supplies the H₂ gas and the N₂ gas from the other path among the two supply paths 42 to guide the H₂ gas to the processing space PS to reduce the WCl₆ gas adsorbed on the surface of the substrate W.

The gas exhaust section 50 exhausts, as an exhaust gas, an unreacted processing gas supplied to the internal space 10s of the processing chamber 10, a reactant generated by the reaction of the processing gas, and the like. In particular, the gas exhaust section 50 according to the present embodiment is configured to uniformly exhaust the exhaust gas from the entire circumference of the substrate W in the circumferential direction.

Specifically, the gas exhaust section 50 has an inner protrusion 51 protruding radially inward from the sidewall 11a of the processing chamber 10 (the chamber body 11), and has an exhaust port 52 continuously formed along the inner circumferential surface of the inner protrusion 51. The gas exhaust section 50 exhausts the exhaust gas in the internal space 10s through the exhaust port 52.

The inner protrusion 51 is located near and below the shower plate 32 in the axial direction (the vertical direction) of the chamber body 11 and is integrally formed with the sidewall 11a. The inner protrusion 51 is formed in an annular shape around the entire circumference of the sidewall 11a in the circumferential direction and has a predetermined thickness along the axial direction. The inner circumferential surface of the inner protrusion 51 faces the processing space PS below the shower plate 32.

Here, the susceptor 20 has a stepped surface 20b lower than the mounting surface 20a beside the mounting surface 20a, and an outer edge of the stepped surface 20b is positioned outside the inner circumferential surface of the inner protrusion 51 in the radial direction. The stepped surface 20b of the susceptor 20 is disposed at a position near the lower surface of the inner protrusion 51 via a gap when the substrate W is raised to the processing position. The mounting surface 20a moved to the processing position is located above the lower surface of the inner protrusion 51, thereby causing the substrate W to face the exhaust port 52.

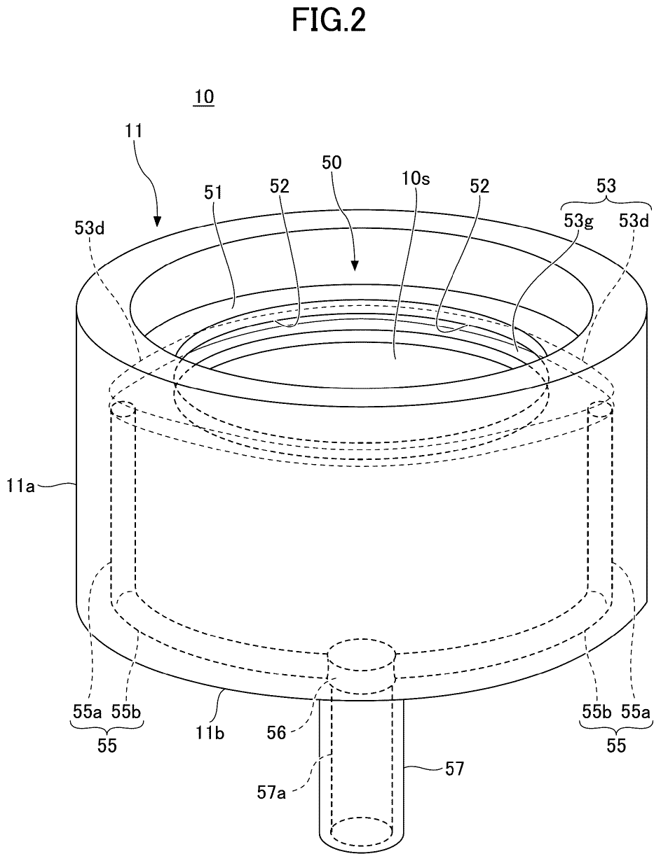

FIG. 2 is a perspective view schematically illustrating a configuration of the chamber body 11. The exhaust port 52 of the gas exhaust section 50 is formed in an annular shape extending over the entire circumference of the inner circumferential surface of the inner protrusion 51, and has a width narrower than the thickness of the inner protrusion 51. The exhaust port 52 is located near the outer edge of the substrate W while facing the processing space PS when the susceptor 20 is raised to the processing position. Therefore, the exhaust port 52 can suction the exhaust gas in the processing space PS at the entire circumference in the circumferential direction and in the horizontal direction. Additionally, the exhaust port 52 communicates with a buffer space 53 formed in a groove shape over the inner protrusion 51 and the sidewall 11a.

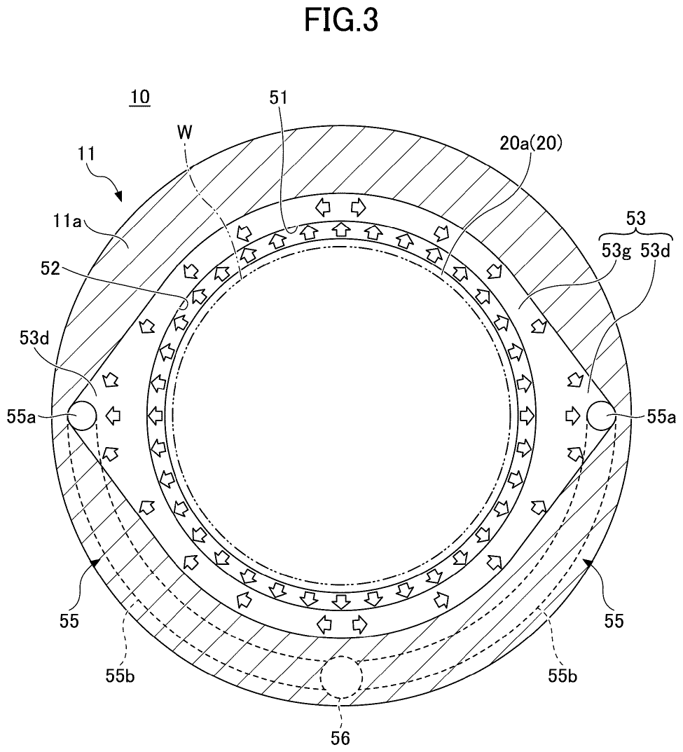

The buffer space 53 is cut out from the inner circumferential surface of the inner protrusion 51 toward the outside in the radial direction (in the horizontal direction). The buffer space 53 has a groove space 53g extending annularly in the inner protrusion 51 and depth spaces 53d communicating with the groove space 53g and deeper than the groove space 53g at two positions shifted in phase by 90° in the circumferential direction from the carry in/out port 15. The two depth spaces 53d are formed in a substantially isosceles triangular shape in a plan sectional view, and the depth with respect to the exhaust port 52 gradually increases toward the vertex angle (see also FIG. 3). With this, the depth space 53d is formed to be smoothly continuous with the groove space 53g from the inner protrusion 51 to the sidewall 11a.

The two depth spaces 53d are provided at symmetrical positions with respect to the axial center of the chamber body 11, and are formed in symmetrical shapes. An exhaust passage 55 for directing the exhaust gas discharged from the exhaust port 52 in the axial direction is communicated at a position near the vertex angle of each of the depth spaces 53d. The vertex angle of each of the depth spaces 53d is formed in a round angle (R shape) corresponding to the circle shape of each of the exhaust passages 55. Additionally, the equal sides constituting the depth space 53d are lines tangent to the circle of the groove space 53g.

Each of the exhaust passages 55 extends in the wall (the sidewall 11a and the bottom wall 11b) constituting the chamber body 11 to guide the exhaust gas along the inside of the wall. In detail, each of the exhaust passages 55 includes a side passage 55a extending in the sidewall 11a of the chamber body 11 and a bottom passage 55b communicating with a lower end of the side passage 55a and extending in the bottom wall 11b of the chamber body 11.

The two side passages 55a extend in a straight line along the vertical direction (the axial direction of the chamber body 11). The side passages 55a are arranged at positions 180° apart from each other in the circumferential direction of the chamber body 11.

The two bottom passages 55b are connected to the side passages 55a in the bottom wall 11b with being bent in an R shape, and extend in an arc shape along the circumferential direction from the connection position with the sidewall 11a near the outer circumferential surface of the bottom wall 11b. The bottom passages 55b extend so as to be close to each other in the bottom wall 11b, and communicate with a joint space 56 formed at a position shifted in phase by 90° in the circumferential direction from the side passages 55a.

As described above, the two exhaust passages 55 including the side passages 55a and the bottom passages 55b are located symmetrically and have a symmetrical shape with the joint space 56 being interposed between the two exhaust passages 55. That is, the two exhaust passages 55 have the same extension length, the same position and the same number of bent portions, and the same shape, and the shape of each of the passages (the diameter, the curvature, the flow passage cross-sectional area, and the like) is also set to be the same.

The joint space 56 is, for example,

positioned in the bottom wall 11b below the carry in/out port 15 and is formed as a cylindrical space extending in a short distance from the inside of the bottom wall 11b to the outside of the chamber body 11. The joint space 56 communicates with a pipe conduit 57a of a discharge port 57 (discharge pipe) provided on the lower surface of the bottom wall 11b of the processing chamber 10. The discharge port 57 is connected to a discharge path 60 (see FIG. 1), through which the processing gas to be exhausted is caused to flow, outside the processing chamber 10.

Returning to FIG. 1, the discharge path 60 includes a suction mechanism 61 configured to suction the processing gas at a middle position thereof, and a disposal section 62 configured to process the exhaust gas at a downstream end thereof. The suction mechanism 61 is configured, for example, by appropriately combining a pressure control (APC) valve for adjusting the pressure in the processing chamber 10, a turbo molecular pump configured to suction the processing gas, a vacuum pump, and the like. The suction mechanism 61 operates under the control of the control device 90 of the substrate processing apparatus 1 and applies a negative pressure for guiding the processing gas in the processing chamber 10. With this, the processing gas in the processing chamber 10 flows out to the discharge path 60 through the exhaust port 52, the buffer space 53, each of the exhaust passages 55, the joint space 56, and the pipe conduit 57a, and is discharged to the disposal section 62 via the discharge path 60.

The control device 90 of the substrate processing apparatus 1 includes a processor 91, a memory 92, an input/output interface, which is not illustrated, an electronic circuit, which is not illustrated, and the like. The processor 91 is one or a combination of a central processing unit (CPU), a graphics processing unit (GPU), an application specific integrated circuit (ASIC), a field-programmable gate array (FPGA), a circuit including multiple discrete semiconductors, and the like. The memory 92 is an appropriate combination of a volatile memory and a nonvolatile memory (for example, a compact disc, a digital versatile disc (DVD), a hard disk, a flash memory, or the like).

The substrate processing apparatus 1 according to the present embodiment is basically configured as described above, and the operation and effect thereof will be described below.

First, the manufacturing of the chamber body 11 including the gas exhaust section 50 will be described. In the manufacturing of the chamber body 11, stainless steel as a base material is used and processed into a body shape having the sidewall 11a, the bottom wall 11b, and the inner protrusion 51 and having no hole, by a known method (cutting, machining, bending, welding, or the like). After the processing of the main body shape, the buffer space 53, the exhaust passages 55, the joint space 56, and the like are formed by a cutting drill or disk. For example, the exhaust port 52 and the buffer space 53 are formed by rotating the inner circumferential surface of the inner protrusion 51 while applying a cutting disk to the inner circumferential surface and adjusting the depth from the inner circumferential surface. Further, in the formation of the side passage 55a and the joint space 56, a hole is formed by advancing a cutting drill from the bottom wall 11b side toward the sidewall 11a. Additionally, in the formation of the bottom passage 55b, a hole is formed by advancing a drill from the sidewall 11a side toward the bottom wall 11b while passing through the side passage 55a. Then, holes that do not contribute to the flow of the exhaust gas (initial positions for advancing the drill) are closed by a closing member and a seal, which are not illustrated, made of the same material as stainless steel, so that the leakage of the exhaust gas is prevented. Here, the shape of the chamber body 11 including the exhaust port 52, the buffer space 53, the exhaust passages 55, and the joint space 56 may be manufactured by using a 3D printer.

Further, in the manufacturing of the processing chamber 10, the heating body 14 is formed on the outer circumferential surface of the chamber body 11 after the processing. As described above, the heating body 14 is formed by first forming the insulating layer 14a by thermal spraying. Then, the interconnect layer 14b is formed (laminated) on the formed insulating layer 14a by thermal spraying. Finally, the insulating layer 14c is formed on the formed interconnect layer 14b by thermal spraying. By the manufacturing method described above, the chamber body 11 including the heating body 14 on the outer circumferential surface can be manufactured with high accuracy.

Next, the substrate processing of the substrate processing apparatus 1 according to the present embodiment will be described. As illustrated in FIG. 1, the substrate processing apparatus 1 first opens the gate valve 16, and transfers the substrate W into the processing chamber 10 by the transfer device, and delivers the substrate W to the support pins 27b protruding from the lower side. Subsequently, the substrate processing apparatus 1 retracts the transfer device from the processing chamber 10, closes the gate valve 16, and lowers the support pins 27b to mount the substrate W on the mounting surface 20a of the susceptor 20 at the transfer position. The control device 90 of the substrate processing apparatus 1 heats the substrate W by the heater 21 of the susceptor 20 and heats the entire processing chamber 10 by the heating body 14 after the substrate W is disposed. With this, the temperature in the processing chamber 10 is increased to a temperature required for the substrate processing (for example, 450° C. to 650° C.).

Additionally, the control device 90 raises the susceptor 20 to the processing position to bring the substrate W close to the shower plate 32 and the inner protrusion 51. After the susceptor 20 is raised, the control device 90 operates the pump of the suction mechanism 61 to perform suction in the processing chamber 10, and adjusts the pressure in the processing chamber 10 to a predetermined pressure by the pressure control valve of the suction mechanism 61.

The control device 90 controls the gas supply system 41 to supply the N₂ gas and the WCl₆ gas into the processing chamber 10 from the gas supply system 41, and cause the WCl₆ gas to be adsorbed on the surface of the substrate W. Further, the control device 90 controls the gas supply system 41 to supply the H₂ gas and the N₂ gas from the gas supply system 41 into the processing chamber 10 to reduce the WCl₆ gas adsorbed on the surface of the substrate W. The control device 90 deposits a tungsten film having a desired thickness by repeating the adsorption of the WCl₆ gas and the reduction of the WCl₆ gas multiple times (for example, 50 to 1000 cycles).

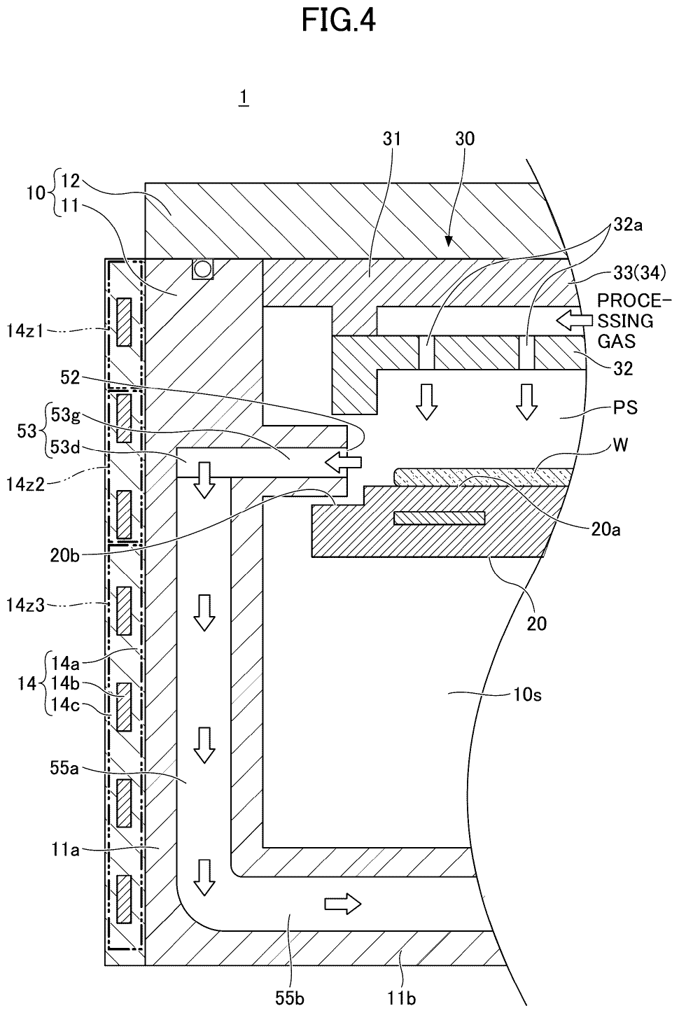

FIG. 3 is a plan sectional view of the chamber body 11 at the position where the exhaust port 52 is formed. FIG. 4 is an enlarged side sectional view of a part the configuration of the gas exhaust section 50. As illustrated in FIG. 3 and FIG. 4, the gas exhaust section 50 continuously exhausts the exhaust gas in the internal space 10s based on the suction operation of the exhaust gas by the suction mechanism 61 during the film deposition process.

At this time, the annular exhaust port 52 formed in the inner circumferential surface of the chamber body 11 (the inner protrusion 51) can guide the exhaust gas from the entire circumference in the circumferential direction of the substrate W toward the outside the substrate W in the radial direction. Specifically, when the exhaust gas in the internal space 10s flows into the buffer space 53 from the exhaust port 52, the exhaust gas flows toward the exhaust passages 55 of the two depth spaces 53d in the buffer space 53. However, while in the vicinity of each of the depth spaces 53d, the exhaust gas gathers and thus the flow property (ease of flow) of the exhaust gas is weakened, in the groove space 53g away from each of the depth spaces 53d, the exhaust gas becomes thin and thus the flow property of the exhaust gas is strengthened. As a result, the gas exhaust section 50 does not apply a large negative pressure to the exhaust port 52 located near the position where each of the depth spaces 53d is formed, but the gas exhaust section 50 can apply a uniform negative pressure to the entire exhaust port 52. That is, the gas exhaust section 50 can radially draw the exhaust gas present near the substrate W in the entire circumference of the outer edge of the substrate W.

Additionally, the two depth spaces 53d are formed at symmetrical positions and in symmetrical shapes with the center axis being interposed, so that the conductance of the exhaust gas branching and flowing in the buffer space 53 can be identical. Therefore, in the buffer space 53, the exhaust gas smoothly branches and flows toward the exhaust passage 55 of each of the depth spaces 53d. In particular, the exhaust port 52 and the buffer space 53 are located at the height position the same as the substrate W, and thus the exhaust gas can be immediately suctioned from the substrate W in the horizontal direction, and the in-plane uniformity in the substrate processing can be further improved by suppressing the convection and the turbulent flow in the processing space PS.

Then, when the exhaust gas moves to the vicinity of the vertex angle of each of the depth spaces 53d, the exhaust gas flows into the corresponding exhaust passage 55. The exhaust gas reaches the joint space 56 through the side passage 55a and the bottom passage 55b of each of the exhaust passages 55. The two exhaust passages 55 are also formed in a symmetrical shape as described above, and thus the conductance of the exhaust gas can be identical. Therefore, each of the exhaust passages 55 can stably guide the same amount of exhaust gas to the joint space 56.

Additionally, the heating body 14 is adjacent to the side of each of the side passages 55a, and the exhaust gas flowing through the side passage 55a is heated by the heating body 14. Thus, the exhaust gas is prevented from becoming deposits due to the decrease in temperature. Therefore, the gas exhaust section 50 can effectively suppress the adhesion of the deposits to the inner circumferential surface of each of the exhaust passages 55, and can suppress the decrease in conductance, clogging, or the like of each of the exhaust passages 55.

Here, the heating body 14 disposed on the outer circumferential surface of the processing chamber 10 may be configured to selectively and independently heat multiple zones obtained by dividing, so that heating with high output or heating with low output can be adjusted for any portion of the processing chamber 10. As illustrated in FIG. 4, the multiple zones of the heating body 14 are obtained by the division along the axial direction (vertical direction) of the processing chamber 10. Examples of the multiple zones include a zone 14z1 disposed at a position adjacent to the shower plate 32, a zone 14z2 disposed at a position corresponding to the exhaust port 52, and a zone 14z3 disposed at a position corresponding to the side passage 55a.

For example, the processing chamber 10 is configured such that the vicinity of the outer peripheral portion of the substrate W is disposed close to the exhaust port 52 during the substrate processing. In this case, the amount of the gas passing through the outer peripheral portion of the substrate W increases, and heat is easily escaped in comparison with the central portion of the substrate W. When the temperature of the susceptor 20 is low in the processing chamber 10, the temperature gradient in the surface of the substrate W increases, and the temperature of the outer peripheral portion may be significantly decreased. Thus, by increasing the amount of heating in the zone 14z2 of the heating body 14 in the vicinity of the outer peripheral portion of the substrate W in comparison with another zone 14z3, the heat dissipation in the outer peripheral portion of the substrate W is covered, thereby improving the in-plane uniformity. Further, by adjusting the heating amount in the zone 14z1, the outer peripheral portion of the shower plate 32 can be effectively increased.

Additionally, the processing chamber 10 includes the exhaust passage 55 and the joint space 56 in the continuous (integrally formed) sidewall 11a and bottom wall 11b, and thus, the exhaust gas can be smoothly flowed by increasing the conductance of the exhaust gas while preventing the exhaust gas from leaking. Additionally, the chamber body 11 can suppress an increase in the size of the apparatus, complication of assembly, and the like due to the use of multiple members.

After the substrate processing, the substrate processing apparatus 1 stops the supply of the processing gas by the gas supply system 41 and temporarily stops the operation of the suction mechanism 61. Then, the substrate processing apparatus 1 carries the substrate W out from the processing chamber 10 in a procedure reverse to the procedure at the time of carrying the substrate W in the processing chamber 10. With this, the film deposition process on the substrate W accommodated in the processing chamber 10 is completed, and the next substrate W is carried in the processing chamber 10.

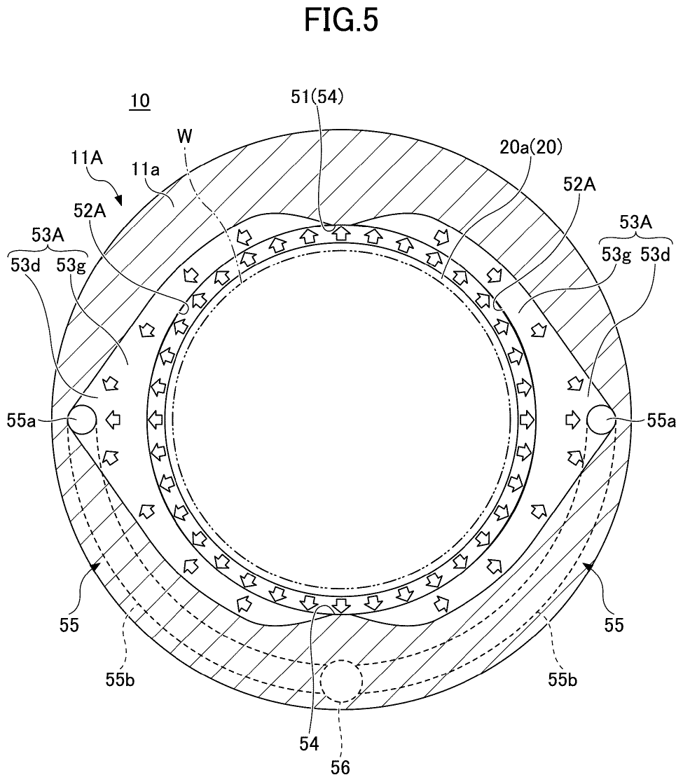

Here, the substrate processing apparatus 1 according to the present disclosure is not limited to the embodiment described above, and various modifications can be made. In the following, a chamber body 11A according to a modified example will be described in detail with reference to FIG. 5. FIG. 5 is a plan sectional view of the chamber body 11A at a position where an exhaust port 52A is formed.

The chamber body 11A of the substrate processing apparatus 1 according to the modified example is different from the chamber body 11 according to the embodiment described above in that exhaust ports 52A that are equal in number to the number of the two exhaust passages 55 are provided on the inner circumferential surface. Specifically, the two exhaust ports 52A are formed at symmetrical positions and in symmetrical shapes on the inner circumferential surface of the inner protrusion 51 protruding from the sidewall 11a of the chamber body 11A.

Each of the exhaust ports 52A has an arc shape extending over substantially half the circumference (substantially 180°) of the inner circumferential surface of the inner protrusion 51. For example, each of the exhaust ports 52A is formed in a range of 175° or greater and less than 180° in the circumferential direction of the inner protrusion 51. Partition walls 54 are provided between circumferential ends of the exhaust ports 52A to partition the exhaust ports 52A. The formation range of each of the partition walls 54 is set to be sufficiently narrower than the formation range of each of the exhaust ports 52A. As an example, on the inner circumferential surface of the inner protrusion 51, while the total of the formation ranges of the exhaust ports 52A is set to 35/36 or greater, the total of the formation ranges of the partition walls 54 is preferably set to 1/36 or less.

The exhaust ports 52A respectively communicate with buffer spaces 53A cut out by the inner protrusion 51 and the sidewall 11a. Each of the buffer spaces 53A is formed in a groove shape that is continuous over the entire circumference of the exhaust port 52A where the buffer space 53A communicates. Each of the buffer spaces 53A (groove spaces 53g) that continue near both ends of the exhaust port 52A in the circumferential direction is formed such that the depth with respect to the exhaust port 52A gradually decreases toward the outer side in the circumferential direction. A depth space 53d having an isosceles triangular shape is formed in each of the buffer spaces 53A that continue at the intermediate portion of the corresponding exhaust port 52A in the circumferential direction. The depth of each of the depth spaces 53d with respect to the exhaust port 52A gradually increases toward the vertex angle, and each of the exhaust passages 55 communicates in the vicinity of the corresponding vertex angle. Here, the exhaust passage 55 in the chamber body 11A has the same configuration as the exhaust passage 55 in the chamber body 11 described above.

The gas exhaust section 50 formed as described above causes the exhaust gas to flow into each of the two buffer spaces 53A in a state where the exhaust gas is divided in advance for the two exhaust ports 52A in the exhaust of the exhaust gas. That is, one exhaust gas of approximately 180° flows into one exhaust port 52A based on the suction action of the one buffer space 53A and the one exhaust passage 55. The other exhaust gas of approximately 180° flows into the other exhaust port 52A based on the suction action of the other buffer space 53A and the other exhaust passage 55. The conductance of the one buffer space 53A is the same as the conductance of the other buffer space 53A, and thus the exhaust gas also flows in the same manner.

In particular, while the exhaust gas gathers in the vicinity of the depth spaces 53d in the buffer space 53A and thus the flow property (ease of flow) of the exhaust gas is weakened, in the groove space 53g away from each of the depth spaces 53d, the exhaust gas becomes thin and thus the flow property of the exhaust gas is strengthened. Therefore, with respect to the exhaust ports 52A, a uniform negative pressure can also be applied over the entire circumference. Therefore, the gas exhaust section 50 can uniformly exhaust the exhaust gas even in the configuration having the two exhaust ports 52A.

In short, the number of the exhaust ports 52 and the number of the buffer spaces 53 are not particularly limited as long as the substrate processing apparatus 1 includes multiple exhaust passages 55. Of course, three or more exhaust passages 55 may be provided. The number of the exhaust ports 52 and the number of the buffer spaces 53 may be configured such that the number thereof is set to be equal to the number of the multiple exhaust passages 55 and respectively communicate with the exhaust passages 55, or may be configured such that the number thereof is set to be less than the number of the multiple exhaust passages 55 and multiple exhaust ports 52 and multiple buffer spaces 53 communicate with one exhaust passage 55.

Additionally, as another modified example, the substrate processing apparatus 1 may have a configuration in which the multiple exhaust passages 55 are joined to each other outside the processing chamber 10, instead of the configuration in which the multiple exhaust passages 55 are joined to each other in the joint space 56 in the processing chamber 10. In this case, it is preferable that a pipe communicating with each of the multiple exhaust passages 55 is connected and the pipe is formed in the same shape up to the joint point. With this, the conductance applied to the exhaust gas can be equal, and the exhaust gas can be uniformly diffused in the processing chamber 10.

The technical ideas and effects of the present disclosure described in the above embodiments will be described below.

A first aspect of the present disclosure includes the processing chamber 10 accommodating the substrate W in the internal space 10s, the susceptor 20 mounting the substrate W in the internal space 10s, the gas supply 40 configured to supply the processing gas to the internal space 10s, and the gas exhaust section 50 configured to exhaust the exhaust gas containing the processing gas from the internal space 10s. The gas exhaust section 50 includes one or more exhaust ports 52 or 52A that communicate with the internal space 10s of the processing chamber 10 and extend along the circumferential direction of the inner circumferential surface of the processing chamber 10, the exhaust gas flowing into the one or more exhaust ports 52 or 52A, and multiple exhaust passages 55 that communicate the one or more exhaust ports 52 or 52A and extend inside the wall of the processing chamber 10.

According to the above description, the

substrate processing apparatus 1 includes the multiple exhaust passages 55 that communicate with the one or more exhaust ports 52 or 52A, so that the exhaust gas can be caused to uniformly flow in the processing chamber 10, thereby improving the in-plane uniformity of the substrate processing. That is, the substrate processing apparatus 1 can uniformly apply a negative pressure to the one or more exhaust ports 52 or 52A extending along the inner circumferential surface of the processing chamber 10 from each of the multiple exhaust passages 55 provided in the wall of the processing chamber 10. As a result, the exhaust gas in the internal space 10s of the processing chamber 10 can be uniformly diffused toward the exhaust port 52 or 52A, and the supply of the processing gas to the substrate W can be stabilized.

Additionally, at least a portion of the processing chamber 10 where the multiple exhaust passages 55 are formed is integrally formed. With this, with respect to the exhaust gas flowing through the multiple exhaust passages 55, the substrate processing apparatus 1 can smoothly flow the exhaust gas without a decrease in the conductance due to the difference in the members.

Additionally, the multiple exhaust passages 55 are disposed at positions spaced apart from each other at equal intervals along the circumferential direction of the processing chamber 10. With this, the substrate processing apparatus 1 can diffuse the processing gas more uniformly.

Additionally, the multiple exhaust passages 55 include the side passages 55a communicating with the exhaust port 52 or 52A and extending inside the sidewall 11a of the processing chamber 10, and the bottom passages 55b communicating with the side passage 55a and extending inside the bottom wall 11b of the processing chamber 10. The multiple side passages 55a are formed in the same shape, and the multiple bottom passages 55b are formed in the same shape. With this, the substrate processing apparatus 1 applies the same conductance to the exhaust gas in the multiple exhaust passages 55, and the exhaust gas flowing through the multiple exhaust passages 55 can be equal.

Additionally, the buffer spaces 53 are provided between the one or more exhaust ports 52 or 52A and the multiple exhaust passages 55, the buffer spaces 53 include the depth spaces 53d that continue toward the multiple exhaust passages 55, and the multiple depth spaces 53d are formed in the same shape. With this, the substrate processing apparatus 1 can apply the same conductance to the exhaust gas even in the multiple depth spaces 53d.

Additionally, the depth space 53d is formed to have equal angles and equal sides with a position where the exhaust passage 55 communicates as a base point. With this, the substrate processing apparatus 1 can smoothly guide the exhaust gas flowing into the buffer space 53 to the depth space 53d and easily cause the exhaust gas to gather in the depth space 53d. As a result, the flow property of the exhaust gas in the vicinity of the depth space 53d is weakened, and the flow property of the exhaust gas at a location away from the depth space 53d is strengthened, and therefore, substantially the same negative pressure can be applied to the entire circumference of the exhaust port 52 or 52A in the circumferential direction.

Additionally, the heating body 14 configured to heat the processing chamber 10 is provided on the outer circumferential surface of the wall of the processing chamber 10. With this, the substrate processing apparatus 1 can heat the exhaust gas flowing through the exhaust passage 55 by the heating body 14, and can suppress the generation of deposits in the exhaust passage 55.

Additionally, the processing chamber 10 is formed of a low thermal expansion material, and the heating body 14 is a thermal spray heater formed by performing thermal spraying on the surface of the wall of the processing chamber 10. With this, in the substrate processing apparatus 1, the heating body 14 can be easily provided on the entire target surface of the processing chamber 10, and a higher temperature can be promoted even in the processing chamber 10 having a low heat transfer rate due to stainless steel.

Additionally, the heating body 14 is divided into multiple zones 14z1, 14z2, and 14z3 along the axial direction of the processing chamber 10, and the heating amount can be adjusted for each of the multiple zones 14z1, 14z2, and 14z3. With this, the substrate processing apparatus 1 can appropriately heat the processing chamber 10 according to the temperature distribution in the processing chamber 10.

Additionally, at least one of the multiple zones 14z1, 14z2, and 14z3 is disposed at a position adjacent to one or more exhaust ports 52 or 52A in the horizontal direction, and is adjusted to a heating amount higher than the heating amount of the other zones. With this, the substrate processing apparatus 1 can increase the temperature in the vicinity of the exhaust port 52 or 52A, where the temperature easily decreases, and suppress a temperature decrease in the outer peripheral portion of the substrate W disposed in the vicinity thereof.

Additionally, the processing chamber 10 includes the inner protrusion 51 protruding toward the substrate W mounted on the susceptor 20, and the exhaust port 52 or 52A is provided on the inner circumferential surface of the inner protrusion 51. With this, the substrate processing apparatus 1 can dispose the exhaust port 52 or 52A at a position near the outer edge of the substrate W, and can immediately exhaust the processing gas supplied to the substrate W.

Additionally, the exhaust port 52 is formed in an annular shape extending over the entire circumference of the inner circumferential surface of the processing chamber 10, and the multiple exhaust passages 55 are provided at symmetrical positions with the center of the processing chamber 10 being interposed. With this, the substrate processing apparatus 1 can suction the exhaust gas from the entire annular exhaust port 52, and can more stably perform the substrate processing.

Additionally, the one or more exhaust ports 52A are provided to be equal in number to the number of the multiple exhaust passages 55 and respectively communicate with the plurality of exhaust passages 55, and the partition wall 54 that is shorter than the extension length of the exhaust port 52A is provided between the multiple exhaust ports 52A. With this, even when the substrate processing apparatus 1 includes multiple exhaust ports 52A, the substrate processing apparatus 1 can suction the exhaust gas from the entire circumference of the processing chamber 10 in the circumferential direction through the multiple exhaust ports 52A.

Additionally, the processing chamber 10 is accommodated in the outer chamber 17, and the support (a ball-shaped member 18) supporting the processing chamber 10 with a gap from the outer chamber 17 is disposed between the bottom surface of the outer chamber 17 and the processing chamber 10. With this, the substrate processing apparatus 1 can further improve the heat insulation property of the processing chamber 10.

Additionally, a second aspect of the present disclosure is the substrate processing method of processing the substrate W, including: a step of mounting the substrate W on the susceptor 20 disposed in the internal space 10s of the processing chamber 10; and a step of supplying the processing gas to the internal space 10s by the gas supply 40 and exhausting the exhaust gas containing the processing gas from the internal space 10s by the gas exhaust section 50. In the step of exhausting the exhaust gas, after the exhaust gas is caused to flow into the one or more exhaust ports 52 or 52A communicating with the internal space 10s of the processing chamber 10 and extending along the circumferential direction of the inner circumferential surface of the processing chamber 10, the exhaust gas is caused to flow through the multiple exhaust passages 55 communicating with the one or more exhaust ports 52 or 52A and extending inside the wall of the processing chamber 10. In this case, the substrate processing method can also improve the in-plane uniformity of the substrate processing by causing the exhaust gas to uniformly flow in the processing chamber 10.

The substrate processing apparatus 1 according to the embodiments disclosed herein is illustrative and not restrictive in all respects. The embodiments can be modified and improved in various forms without departing from the scope and spirit of the appended claims. The matters described in the above embodiments can take another configuration to the extent that there is no contradiction, and can be combined together to the extent that there is no contradiction.

The substrate processing apparatus 1 of the present disclosure may be applied to any type of apparatus, such as an atomic layer deposition (ALD) apparatus, a capacitively coupled plasma (CCP) apparatus, an inductively coupled plasma (ICP) apparatus, a radial line slot antenna (RLSA) apparatus, an electron cyclotron resonance plasma (ECR) apparatus, or a helicon wave plasma (HWP) apparatus.

This application claims priority to Basic Application No. 2022-048862, filed with the Japanese Patent Office on Mar. 24, 2022, and Domestic Priority Application No. 2022-134010, filed with the Japanese Patent Office on Aug. 25, 2022, the entire contents of which are incorporated herein by reference.

### DESCRIPTION OF REFERENCE SYMBOLS

1 substrate processing apparatus
10 processing chamber
10s internal space
20 susceptor
40 gas supply
50 gas exhaust section
52, 52A exhaust port
55 exhaust passage
W substrate

1. A substrate processing apparatus comprising:
a processing chamber configured to accommodate a substrate in an internal space;
a susceptor configured to mount the substrate in the internal space;
a gas supply configured to supply a processing gas to the internal space; and
a gas exhaust section configured to exhaust an exhaust gas containing the processing gas from the internal space,
wherein the gas exhaust section includes one or more exhaust ports communicating with the internal space of the processing chamber and extending along a circumferential direction of an inner circumferential surface of the processing chamber, the exhaust gas flowing into the one or more exhaust ports, and a plurality of exhaust passages communicating with the one or more exhaust ports and extending inside a wall of the processing chamber.

2. The substrate processing apparatus as claimed in claim 1, wherein at least a portion of the processing chamber where the plurality of exhaust passages are formed is integrally formed.

3. The substrate processing apparatus as claimed in claim 1, wherein the plurality of exhaust passages are disposed at positions spaced apart from each other at equal intervals along a circumferential direction of the processing chamber.

4. The substrate processing apparatus as claimed in claim 1,
wherein the plurality of exhaust passages include side passages communicating with the one or more exhaust ports and extending inside a sidewall of the processing chamber, and bottom passages communicating with the side passages and extending inside a bottom wall of the processing chamber, and
wherein the side passages are formed in a same shape, and the bottom passages are formed in a same shape.

5. The substrate processing apparatus as claimed in claim 1,
wherein a buffer space is provided between the one or more exhaust ports and the plurality of exhaust passages,
wherein the buffer space has depth spaces that continue toward each of the plurality of exhaust passages, and
wherein the depth spaces are formed in a same shape.

6. The substrate processing apparatus as claimed in claim 5, wherein the depth spaces are formed to have equal angles and equal sides with positions where the plurality of exhaust passages communicate as base points.

7. The substrate processing apparatus as claimed in claim 1, wherein a heating body configured to heat the processing chamber is provided on an outer circumferential surface of the wall of the processing chamber.

8. The substrate processing apparatus as claimed in claim 7,
wherein the processing chamber is formed of a low thermal expansion material, and
wherein the heating body is a thermal spray heater formed by performing thermal spraying on a surface of the wall of the processing chamber.

9. The substrate processing apparatus as claimed in claim 7, wherein the heating body is divided into a plurality of zones along an axial direction of the processing chamber, and a heating amount is adjustable for each of the plurality of zones.

10. The substrate processing apparatus as claimed in claim 9, wherein at least one of the plurality of zones is disposed at a position adjacent to the one or more exhaust ports in a horizontal direction, and is adjusted to a heating amount higher than a heating amount of other zones.

11. The substrate processing apparatus as claimed in claim 1,
wherein the processing chamber has an inner protrusion protruding toward the substrate mounted on the susceptor, and
wherein the one or more exhaust ports are provided on the inner circumferential surface of the inner protrusion.

12. The substrate processing apparatus as claimed in claim 1,
wherein the one or more exhaust ports are formed in an annular shape extending over an entire circumference of the inner circumferential surface of the processing chamber, and
wherein the plurality of exhaust passages are provided at symmetrical positions with a center of the processing chamber being interposed.

13. The substrate processing apparatus as claimed in claim 1,
wherein the one or more exhaust ports are provided equal in number to a number of the plurality of exhaust passages and respectively communicate with the plurality of exhaust passages, and
wherein a partition wall shorter than an extension length of the one or more exhaust ports is provided between the plurality of exhaust ports.

14. The substrate processing apparatus as claimed in claim 1,
wherein the processing chamber is accommodated in an outer chamber, and
wherein a support configured to support the processing chamber with a gap from the outer chamber is disposed between a bottom surface of the outer chamber and the processing chamber.

15. A substrate processing method of processing a substrate, the substrate processing method comprising:
mounting the substrate on a susceptor disposed in an internal space of a processing chamber; and
supplying a processing gas to the internal space by a gas supply and exhausting an exhaust gas containing the processing gas from the internal space by a gas exhaust section,
wherein, in the exhausting the exhaust gas, after the exhaust gas is caused to flow into one or more exhaust ports communicating with the internal space of the processing chamber and extending along a circumferential direction of an inner circumferential surface of the processing chamber, the exhaust gas is caused to flow through a plurality of exhaust passages communicating with the one or more exhaust ports and extending inside a wall of the processing chamber.
